(19) United States
(12) Patent Application Publication
(10) Pub. No.: US 2026/0271782 A1
(43) Pub. Date: Sep. 10, 2026

(54) TECHNOLOGIES FOR BASE DIE PLACEMENT IN HIGH-BANDWIDTH MEMORY SYSTEMS

(71) Applicant: Intel Corporation, Santa Clara, CA (US)

(72) Inventors: Abhishek Anil Sharma, Portland, OR (US); Anand V. Iyer, Saratoga, CA (US); Nitin A. Deshpande, Chandler, AZ (US); Prashant Majhi, San Jose, CA (US); Christopher M. Pelto, Beaverton, OR (US)

(73) Assignee: Intel Corporation, Santa Clara, CA (US)

(21) Appl. No.: 19/075,591

(22) Filed: Mar. 10, 2025

(51) Int. Cl. H10W 90/00; H10B 80/00; H10D 80/30; H10W 40/22; H10W 70/60; H10W 80/00; H10W 90/20

(52) U.S. Cl. CPC H10W 90/00; H10B 80/00; H10D 80/30; H10W 40/22; H10W 70/611; H10W 90/401; H10W 80/211; H10W 80/312; H10W 80/327; H10W 90/288; H10W 90/297; H10W 90/724; H10W 90/792

(57) ABSTRACT

Technologies for base die placement in high-bandwidth memory (HBM) systems are disclosed. In an illustrative embodiment, the base die or interface die for an HBM die stack may be positioned in the middle of the HBM die stack. Positioning the interface die in the middle can balance timings between various memory dies in the HBM die stack better than positioning the interface die at the bottom. The balanced timing can improve performance, allowing for higher bandwidth and/or more HBM memory dies in the stack. Through-silicon vias extend from the interface die, through one or more memory dies, and to microbumps at the bottom of the HBM die stack. In some embodiments, the interface die may be positioned closer to or at the top of the HBM die stack, closer to the heat sink. Such a placement may facilitate heat removal from the interface die.

### BACKGROUND

High-bandwidth memory (HBM) is an advanced memory technology designed to provide significantly higher data transfer rates and power efficiency compared to conventional DRAM solutions. HBM systems achieve this by vertically stacking multiple memory dies and connecting the dies using through-silicon vias (TSVs), which provide dense, low-latency communication pathways to a nearby processor. These stacks are then mounted onto a silicon interposer or an embedded bridge, allowing for wide parallel data buses between the memory and the processor.

HBM offers several key advantages over traditional memory architectures. Its high bandwidth per watt makes it particularly well-suited for applications requiring massive data throughput, such as artificial intelligence (AI), machine learning (ML), high-performance computing (HPC), and graphics processing. Additionally, its compact form factor reduces the overall footprint on a package, enabling more efficient use of space in tightly integrated systems. By keeping memory closer to the processor and minimizing the distance data must travel, HBM significantly reduces latency and improves energy efficiency.

The capacity of HBM can be increased by stacking more memory dies. However, stacking more memory dies can lead to several challenges, such as a larger difference in signal path from different memory dies and an increased heat load, particularly at the interface with the interposer or bridge die.

### BRIEF DESCRIPTION OF THE DRAWINGS

FIG. 1 is an isometric view of one embodiment of a system with a processor and several high-bandwidth memory (HBM) stacks on a circuit board.

FIG. 2 is a cross-sectional view of one embodiment of the system of FIG. 1.

FIG. 3 is a cross-sectional view of one embodiment of an HBM stack of FIG. 1.

FIG. 4 is a cross-sectional view of one embodiment of an HBM stack of FIG. 1.

FIG. 5 is a cross-sectional view of one embodiment of an HBM stack of FIG. 1.

FIG. 6 is a flowchart of one embodiment of a method of creating one embodiment of the system of FIG. 1.

FIG. 7 is a cross-sectional view of one embodiment of an HBM die stack at one stage of the flowchart of FIG. 6.

FIG. 8 is a cross-sectional view of one embodiment of an HBM die stack at one stage of the flowchart of FIG. 6.

FIG. 9 is a cross-sectional view of one embodiment of an HBM die stack at one stage of the flowchart of FIG. 6.

FIG. 10 is a cross-sectional view of one embodiment of an HBM die stack at one stage of the flowchart of FIG. 6.

FIG. 11 is a cross-sectional view of one embodiment of an HBM die stack at one stage of the flowchart of FIG. 6.

FIG. 12 is a cross-sectional view of one embodiment of an HBM die stack at one stage of the flowchart of FIG. 6.

FIG. 13 is a top view of a wafer and dies that may be included in a microelectronic assembly, in accordance with any of the embodiments disclosed herein.

FIG. 14 is a cross-sectional side view of an integrated circuit device that may be included in a microelectronic assembly, in accordance with any of the embodiments disclosed herein.

FIGS. 15A-15D are perspective views of example planar, gate-all-around, and stacked gate-all-around transistors.

FIG. 16 is a cross-sectional side view of an integrated circuit device assembly that may include a microelectronic assembly, in accordance with any of the embodiments disclosed herein.

FIG. 17 is a block diagram of an example electrical device that may include a microelectronic assembly, in accordance with any of the embodiments disclosed herein.

### DETAILED DESCRIPTION

In various embodiments disclosed herein, an integrated circuit component has a circuit board with several high-bandwidth memory HBM die stacks and a processor disposed on its surface. Each HBM die stack includes a base die (or interface die) and several memory dies. In an illustrative embodiment, the base die can be positioned at any suitable layer of the HBM die stack, such as in the middle or at the top. The flexible positioning of the base die can offer several benefits, such as balanced timing for signal paths and/or better heat dissipation for hot spots.

As used herein, the phrase “communicatively coupled” refers to the ability of a component to send a signal to or receive a signal from another component. The signal can be any type of signal, such as an input signal, an output signal, or a power signal. A component can send or receive a signal to another component to which it is communicatively coupled via a wired or wireless communication medium (e.g., conductive traces, conductive contacts, air). Examples of components that are communicatively coupled include integrated circuit dies located in the same package that communicate via an embedded bridge in a package substrate and an integrated circuit component attached to a printed circuit board that send signals to or receives signals from other integrated circuit components or electronic devices attached to the printed circuit board.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact, and “coupled” may indicate elements co-operate or interact, but they may or may not be in direct physical or electrical contact. Furthermore, the terms “comprising,” “including,” “having,” and the like, as used with respect to embodiments of the present disclosure, are synonymous. Terms modified by the word “substantially” include arrangements, orientations, spacings, or positions that vary slightly from the meaning of the unmodified term. For example, the central axis of a magnetic plug that is substantially coaxially aligned with a through hole may be misaligned from a central axis of the through hole by several degrees. In another example, a substrate assembly feature, such as a through width, that is described as having substantially a listed dimension can vary within a few percent of the listed dimension.

It will be understood that in the examples shown and described further below, the figures may not be drawn to scale and may not include all possible layers and/or circuit components. In addition, it will be understood that although certain figures illustrate transistor designs with source/drain regions, electrodes, etc. having orthogonal (e.g., perpendicular) boundaries, embodiments herein may implement such boundaries in a substantially orthogonal manner (e.g., within +/- 5 or 10 degrees of orthogonality) due to fabrication methods used to create such devices or for other reasons.

Reference is now made to the drawings, which are not necessarily drawn to scale, wherein similar or same numbers may be used to designate the same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well-known structures and devices are shown in block diagram form in order to facilitate a description thereof. The intention is to cover all modifications, equivalents, and alternatives within the scope of the claims.

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

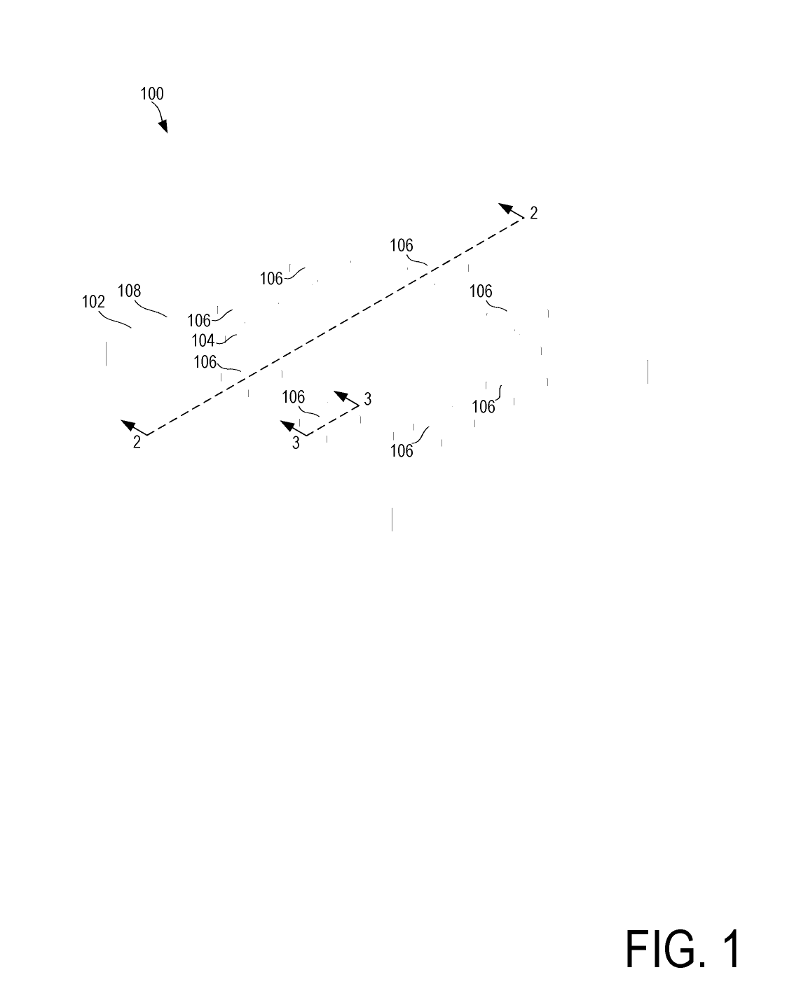

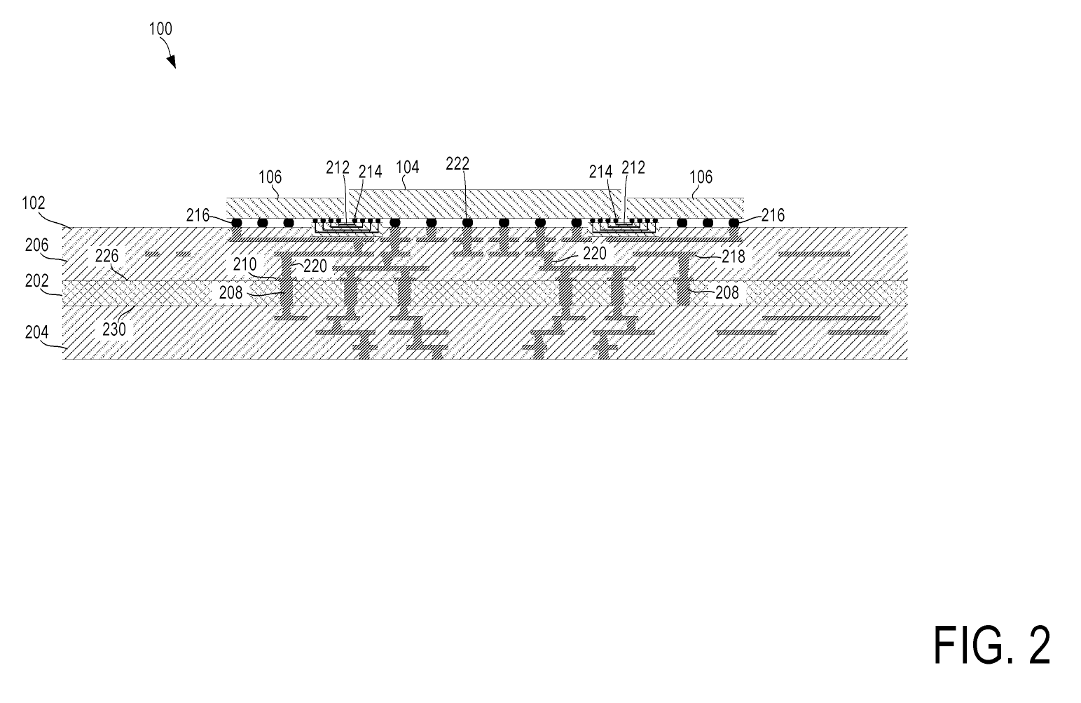

Referring now to FIGS. 1 and 2, in one embodiment, an integrated circuit component 100 includes a circuit board 102 on which one or more dies 104 are mounted. FIG. 1 shows an isometric view of the integrated circuit component 100, and FIG. 2 shows a cross-sectional view of the integrated circuit component 100. As shown in FIG. 1, a die 104 such as a processor die 104 may be disposed on the top surface 108 of the circuit board 102. In an illustrative embodiment, additional components, such as HBM die stacks 106, are disposed on the top surface 108 of the circuit board 102 as well, spread out around the processor die 104.

It should be appreciated that, as used herein, the “top side,” “bottom side,” etc., is an arbitrary designation used for clarity and does not denote a particular required orientation for manufacture or use. Although the illustrative embodiment described has the dies 104 and/or dies in the stack 106 placed on the “top” side of the circuit board 102, in some embodiments, those components may be placed on the “bottom” side of the circuit board 102.

In an illustrative embodiment, the die 104 is a processor die, and the processor die 104 is surrounded by one or more HBM die stacks 106. In other embodiments, the die 104 and/or the die stack 106 may be any suitable die or stack of dies, such as one or more processor dies, memory dies, central processing units (CPUs), graphics processing units (CPUs), any other suitable processing units (xPUs), accelerator circuits, a field-programmable gate arrays (FPGA), application-specific integrated circuits (ASICs), etc. The dies 104 and/or dies of the stack 106 may be connected to contact pads or vias 220 on the circuit board 102 through conductive contacts 222, such as solder balls. In an illustrative embodiment, a bridge die 212 connects each HBM die stack 106 to the processor die 104.

In an illustrative embodiment, the HBM die stacks 106 are a specialized type of dynamic random-access memory (DRAM) designed to deliver significantly higher memory bandwidth while maintaining low power consumption compared to traditional memory technologies like double data rate (DDR) or graphics double data rate (GDDR) DRAM. HBM die stacks 106 achieve this through vertically stacked architecture and a wide interface with the processor, reducing the clock speed requirement and power consumption while providing massive bandwidth. Use of a bridge die 212 allows for high-density, high-bandwidth channels between the HBM die stacks 106 and the processor die 104.

In an illustrative embodiment, the HBM die stacks 106 are compatible with various standards, such as a Universal Chiplet Interface express (UCIe). For example, the HBM die stacks 106 and the communication to and from the HBM die stacks 106 may be compatible with UCIe 1.0, UCIe 1.1, UCIe 2.0., etc. In some embodiments, different protocols or standards may be used, such as Joint Electron Device Engineering Council (JEDEC) HBM (JESD235), HBM2 (JESD235A), HBM2E (JESD235B), HBM3 (JESD238), HBM3 Update (JESD238A), HBM4, Compute Express Link (CXL) 1.0, CXL 2.0, CXL 3.0, CXL 3.1, CXL 3.2, Peripheral Component Interconnect express (PCIE) 3.0, PCIe 4.0, PCIe 5.0, PCIe 6.0, etc.

Each HBM die stack 106 may have any suitable storage capacity and/or bandwidth, such as 4-128 GB capacity and/or 128-1,600 GB/s.

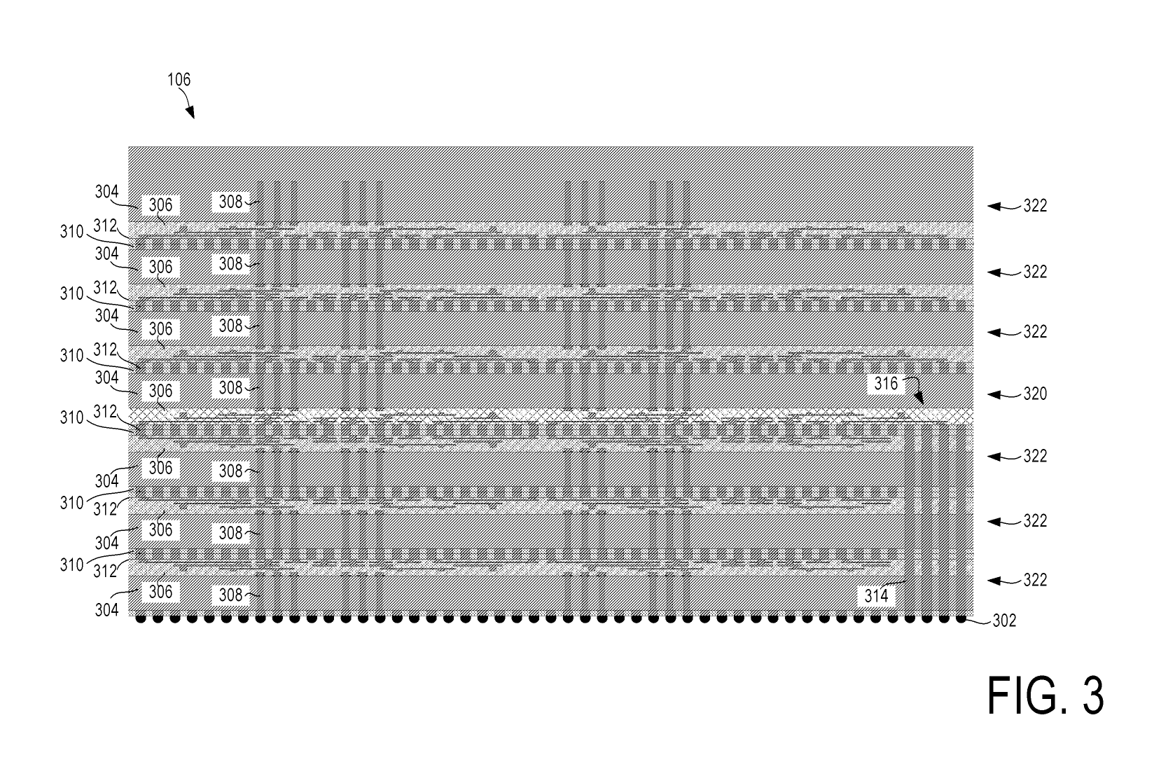

In an illustrative embodiment, each HBM die stack 106 is coupled to the processor die 104 though a bridge die 212. In other embodiments, a silicon interposer may be used, with some or all of the HBM die stack 106 and the processor die 104 mounted on the interposer. In an illustrative embodiment, the bridge die 212 is silicon-based. In other embodiments, the bridge die 212 can be embodied as an organic substrate. The bridge die 212 may be embodied as, e.g., an embedded multi-die interconnect bridge (EMIB). The number of dies in an HBM die stack 106 can vary depending on the application, ranging from a single stack for lower-end devices to 4, 6, or 8 or more stacks for high-performance GPUs and AI accelerators. The HBM die stack 106 is described in more detail below in regard to FIG. 3. As shown in the figure, in an illustrative embodiment, the bridge die 212 is counter-sunk into the circuit board 102.

In an illustrative embodiment, the bridge die 212 is a passive component made of silicon that routes signals between the HBM die stack 106 and the processor die 104. In some embodiments, the bridge die 212 may be an active bridge die, incorporating features such as buffering, signal conditioning, or even computational logic to reduce latency and improve signal integrity. The processor die 104 interfaces with the HBM die stack 106 via a memory controller that implements HBM-specific protocols like HBM2 or HBM3 PHY or other protocols described herein. Data packets may be transferred using burst-mode operations to maximize throughput while minimizing overhead.

In an illustrative embodiment, the HBM die stack 106 and the processor die 104 are coupled to the bridge die 212 using microbumps 214, which may have a pitch of, e.g., 14-50 micrometers. Additionally or alternatively, the HBM die stack 106 and/or the processor die 104 may be coupled to the circuit board 102 using larger solder bumps, such as bumps with a pitch of 40-500 micrometers.

The circuit board 102 includes a substrate core 202, lower build-up layers 204, and upper build-up layers 206. Holes or cavities are defined in the substrate core 202 that extend from the top surface 226 of the substrate core 202 to the bottom surface 230 of the substrate core 202. Vias 208 are disposed in the hole, and pads 210 may be positioned at one or both ends of the vias 208.

In an illustrative embodiment, the circuit board 102 is a multi-layer circuit board 102 with build-up layers 204, 206 above and below the substrate core 202. The build-up layers 204, 206 may have any suitable number of layers, such as 1-10 layers each. In other embodiments, the circuit board 102 may be a single-layer circuit board 102. In an illustrative embodiment, the substrate core 202 is an inorganic core, such as a glass core. The glass core may be silicon oxide glass. In other embodiments, the glass core may be made of any suitable material that may be crystalline, non-crystalline, amorphous, etc., such as fused silicon, borosilicate, sapphire, yttrium aluminum garnet, etc. The glass core may be, e.g., aluminosilicate glass, borosilicate glass, alumino-borosilicate glass, silica, fused silica. The glass core may include one or more additives, such as Al2O3, B2O3, MgO, CaO, SrO, BaO, SnO2, Na2O, K2O, SrO, P2O3, ZrO2, Li2O, Ti, and Zn. The glass core may comprise silicon and oxygen, as well as any one or more of aluminum, boron, magnesium, calcium, barium, tin, sodium, potassium, strontium, phosphorus, zirconium, lithium, titanium, and zinc. The glass core may include at least 20-40 percent silicon by weight, at least 20-40 percent oxygen by weight, and at least 5 percent aluminum by weight. For example, some embodiments of the glass core may include, e.g., at least 20-23 percent silicon and at least 20-26 percent oxygen by weight. In other embodiments, the substrate core 202 may be an organic core, such as a fiberglass board made of glass fibers and a resin, such as FR-4.

The thickness of the circuit board 102 may be any suitable thickness, such as 100 micrometers to 5 millimeters. The thickness of the substrate core 202 may be any suitable thickness, such as 50 micrometers to 2 millimeters. The circuit board 102 can have any suitable length and width, such as 1-500 millimeters. Although shown as a rectangle, it should be appreciated that the circuit board 102 may be any suitable shape and may have protrusions, cutouts, etc., in order to accommodate, fit, or touch other components of a device. In the illustrative embodiment, the circuit board 102 is planar. In other embodiments, the circuit board 102 may be non-planar.

The build-up layers 204, 206 may be made of any suitable material or materials, such as any suitable dielectric that can support the traces 218, vias 220, etc. In an illustrative embodiment, the build-up layers 204, 206 may be made of a resin material filled with a filler, such as Ajinomoto build-up film (ABF).

Referring now to FIG. 3, one embodiment of an HBM die stack 106 includes multiple memory dies 322 and an interface die 320 vertically aligned and interconnected using copper-filled through-silicon vias (TSVs) 308 and pads 312. In an illustrative embodiment, the pads 312 of each memory die 322 and interface die 320 are hybrid bonded to each other, with a dielectric filler 310 between the pads 312. Additionally or alternatively, other connections may be used, such as bump bonding.

Each HBM die stack 106 may include, e.g., 4, 8, or 16 memory dies 322. These dies may be referred to as memory layers, memory dies, or DRAM dies. The HBM die stack 106 also includes an interface die 320. The interface die 320 may be referred to as the base die, the interconnect die, the logic die, etc. The interface die 320 is the logic die, which manages communication with the processor die 104 and data flow within the HBM die stack 106.

Each memory die 322 contains an array of memory cells arranged in banks, with each bank further subdivided into rows and columns for data access. The TSVs are etched through the silicon substrate 304 of each memory die 322, providing high-speed, low-latency connections between the dies. Several logic layers 306 are formed on the substrate 304 for control and data flow, DRAM storage, etc. The diameter of the TSVs may be any suitable value, such as 5-200 micrometers. The pitch for the pads 312 may be any suitable value, such as 10-50 micrometers.

The bottom of the HBM die stack 106 includes an array of microbumps 302. The pitch of the microbumps 302 may be any suitable value, such as 14-40 micrometers. The HBM die stack 106 may include any suitable number of microbumps 302 to connect with the bridge die 212, such as 1,024-4,096. In some embodiments, larger solder bumps 216 may be used to connect the HBM die stack 106 to the circuit board 102, such as for power delivery, lower data rate signals, etc.

The HBM die stack 106 communicates with the processor die 104 through a wide parallel interface of microbumps 302. These lines connect to the processor die 104 via the bridge die 212 or interposer, which routes signals from the microbumps 302 on the HBM die stack 106 microbumps or larger solder bumps on the processor die 104. The interface die 320 includes interface logic 316 to implement protocols to communicate with the processor die 104 and route data on to and off of the HBM die stack 106. The interface logic 316 may employ protocols such as HBM PHY and any of the JEDEC-defined standards referred to above to ensure compatibility and performance. Within the HBM die stack 106, data is organized into channels, with each channel having multiple banks. Data access occurs via row and column commands, with the memory controller on the interface die 320 issuing commands to open or close rows, read or write data, and refresh memory cells. The memory interface may use differential signaling and employ techniques like prefetching and burst transfers to maximize throughput. The interface die 320 may include, e.g., speed testing circuitry, debugging circuitry, direct access circuity, configuration circuitry, backup memory in case of an error in a memory block of any of the memory dies 322, etc.

The HBM die stack 106 may have any suitable dimensions, such as a length and/or width of 5-15 millimeters and a height of 0.4-3 millimeters. In an illustrative embodiment, the HBM die stack 106 has a width (across the page from the perspective of FIG. 3) of about 7.7 millimeters and a length (into and out of the page from the perspective of FIG. 3) of about 11 millimeters. It should be appreciated that the interface logic 316 and microbumps 302 connected to the bridge die 212 extend into and out of the page, allowing for a large number of connections along the shoreline of the HBM die stack 106, improving bandwidth and signal quality. The width of the interface logic 316 and microbumps 302 connected to the bridge die 212 may be, e.g., 200-500 micrometers. In an illustrative embodiment, the width of the interface logic 316 is about 380 micrometers.

Each memory die 322 and/or interface die 320 may have any suitable height, such as 15-200 micrometers. In an illustrative embodiment, part of the silicon substrate 304 of each die is removed as part of manufacturing the HBM die stack 106, leading to small die thicknesses. For example, the thickness of the silicon substrate 304 may be, e.g., 7 micrometers, and the layers 306 built up on the silicon substrate 304 may be, e.g., 8-11 micrometers. The pads 312 on the top and bottom of each die 320, 322 may have a thickness of, e.g., 3-6 micrometers. In some embodiments, the top die 322, 320 may not have its silicon substrate 304 removed (or as much removed), leading to a thicker top die 322, 320.

In an illustrative embodiment, as shown in FIG. 3, the interface die 320 is positioned in the middle of the HBM die stack 106, with an equal number of memory dies 322 above and below the interface die 320. In the embodiment shown, there are three memory dies 322 above and below the interface die 320, but in other embodiments there may be, e.g., 1-16 memory dies 322 above and/or below the interface die 320.

Because the interface die 320 is not on the bottom of the HBM die stack 106, the interface die 320 cannot connect directly to the microbumps 302. To provide a connection between the interface logic 316 and the microbumps 302, through-silicon vias 314 extend through the memory dies 322 between the microbumps 302 and the interface die 320, as shown in FIG. 3. The vias 314 may have similar dimensions, pitch, etc., the TSVs 308 described above. Additionally or alternatively, the vias 314 may be thicker, have a wider pitch, etc., depending on the particular embodiment. In some embodiments, the vias 314 may be embodied as supervias.

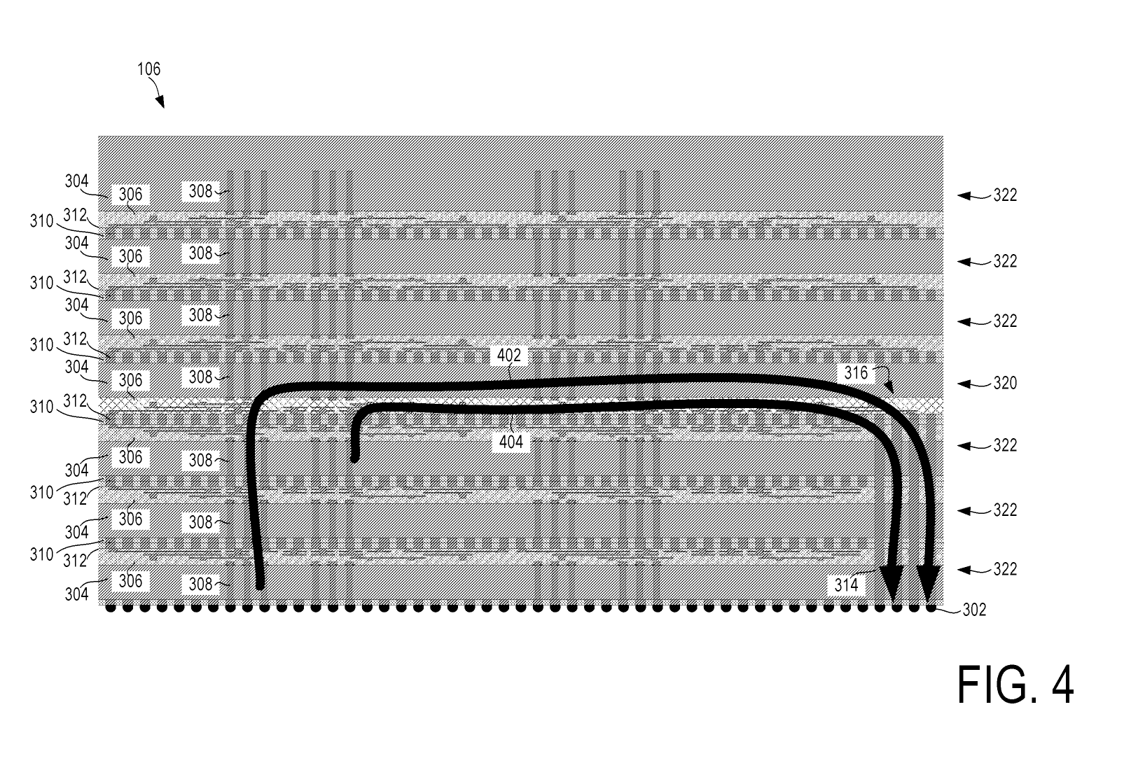

Allowing for a flexible positioning of the interface die 320 can provide several advantages. For example, with the interface die 320 on the bottom, the difference between the signal path length from the closest memory die 322 and the farthest memory die 322 is equal to the number of memory dies 322 minus one. With the interface die 320 in the middle of the HBM die stack 106, the difference between the signal path length from the closest memory die 322 and the farthest memory die 322 is equal to half of the number of memory dies 322 minus one. For example, with six memory dies 322 and the interface die 320 on the bottom of the HBM die stack 106, the biggest difference in path length would be proportional to the thickness of five memory dies in the die stack 106. With the interface die 320 moved to the middle of the HBM die stack 106, the biggest difference in path length is proportional to the thickness of two memory dies in the die stack 106, a decrease of 60%. For example, as shown in FIG. 4, the signal path 402 for the farthest memory die 322 has to pass through only two more memory dies 322 compared to the signal path 404 for the closest memory die 322.

The reduction in mismatch path length can provide several benefits. The smaller path length difference between the closest memory dies 322 and the farther memory dies 322 can provide a balanced timing path, similar to H clock tree routing. The balanced timing can allow for advantages in clock skew management, higher memory transfer rate, simpler control logic, and/or a larger number of memory dies in the HBM die stack 106. In an illustrative embodiment, the interface die 320 and, in particular, the interface logic 316 is a hot spot within the HBM die stack 106. By moving the interface die 320 and interface logic 316 closer to the top of the HBM die stack 106, the interface die 320 and interface logic 316 are closer to the heat sink on the integrated circuit component, removing heat more effectively.

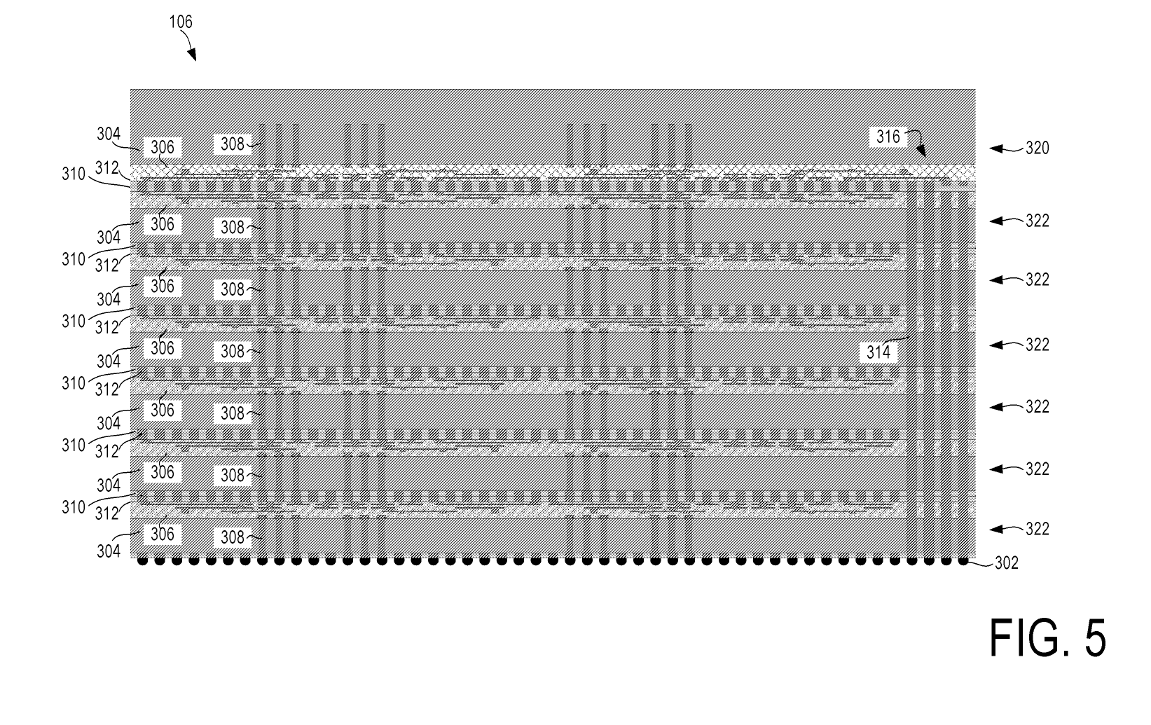

In some embodiments, the interface die 320 may be moved closer to the top or even moved to the top of the HBM die stack 106, as shown in FIG. 5. Moving the interface die 320 closer to the top of the HBM die stack 106 can improve heat dissipation from the interface die 320 and interface logic 316, although moving the interface die 320 closer to the top of the HBM die stack 106 may reduce the balanced timings discussed above. In some embodiments, the interface die 320 may be moved closer to the top relative to the middle of the HBM die stack 106 without being moved all the way to the top, providing a balance of benefits. In general, in various embodiments, the interface die 320 may be positioned at any level within the HBM die stack 106, including at the bottom.

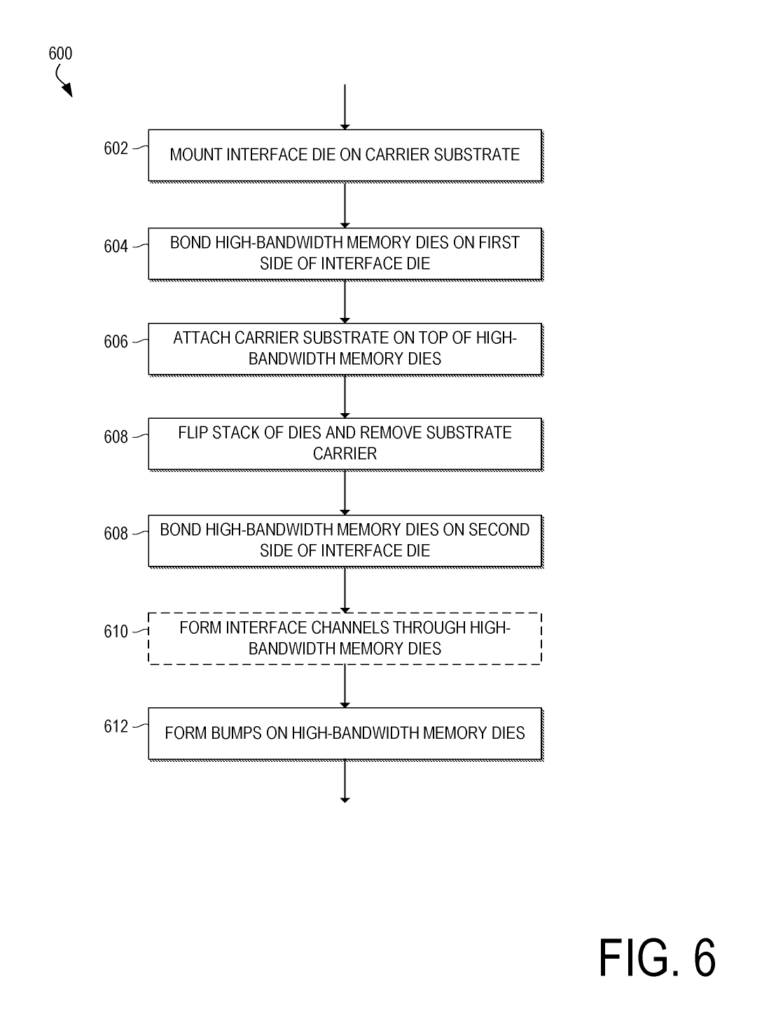

Referring now to FIG. 6, in one embodiment, a flowchart for a method 600 for creating the HBM die stacks 106 for the integrated circuit component 100 is shown. The method 600 may be executed by a technician and/or by one or more automated machines. In some embodiments, one or more machines may be programmed to do some or all of the steps of the method 600. Such a machine may include, e.g., a memory, a processor, data storage, etc. The memory and/or data storage may store instructions that, when executed by the machine, cause the machine to perform some or all of the steps of the method 600. The method 600 may use any suitable set of techniques that are used in semiconductor processing or circuit board processing, such as chemical vapor deposition, atomic layer deposition, physical layer deposition, molecular beam epitaxy, layer transfer, photolithography, ion implantation, dry etching, wet etching, selective laser etching, thermal treatments, flip chip, layer transfer, magnetron sputter deposition, pulsed laser deposition, laser machining, laser-induced deep etching, 3D photolithography, screen printing, ink jet printing, etc. It should be appreciated that the method 600 is merely one embodiment of a method to create one embodiment of a system, and other methods may be used to create any suitable embodiment of the system. In some embodiments, steps of the method 600 may be performed in a different order than that shown in the flowchart.

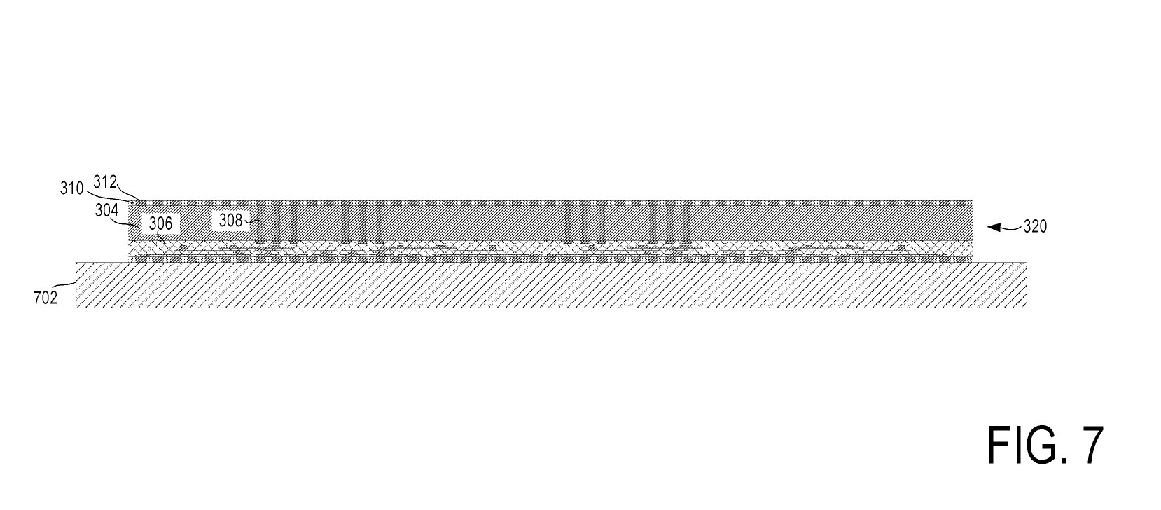

The method 600 begins in block 602, in which an interface die 320 is mounted on a carrier substrate 702, as shown in FIG. 7. The carrier substrate 702 may be embodied as, e.g., silicon, silicon oxide, an organic substrate, etc. In an illustrative embodiment, backside processing may be performed on the interface die 320 at this time. For example, the silicon substrate 304 may be ground down, holes for the TSVs 308 may be etched and filled, pads 312 may be applied, etc. In other embodiments, the interface die 320 may be mounted with backside processing already complete.

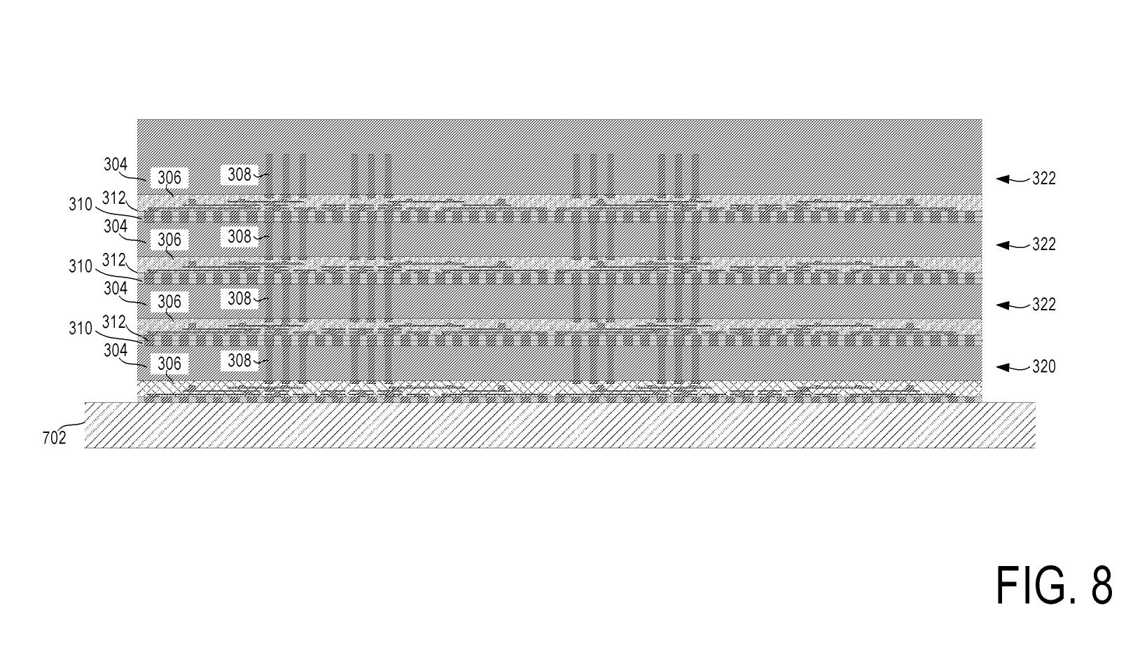

In block 604, one or more HBM memory dies 322 are mounted on the interface die 320, as shown in FIG. 8. In an illustrative embodiment, each memory die 322 is mounted one at a time, and each memory die 322 may undergo back side processing, similar to the interface die 320 described above. In other embodiments, the memory dies 322 may be mounted with backside processing already complete. In such embodiments, two or more memory dies 322 may be mounted at once. In an illustrative embodiment, the memory dies 322 are mounted on the interface die 320 and/or other memory dies 322 using hybrid bonding. Additionally or alternatively, in other embodiments, other approaches may be used, such as solder bump bonding. It should be appreciated that, in some embodiments, the substrate 304 of the top memory die 322 may not be ground down.

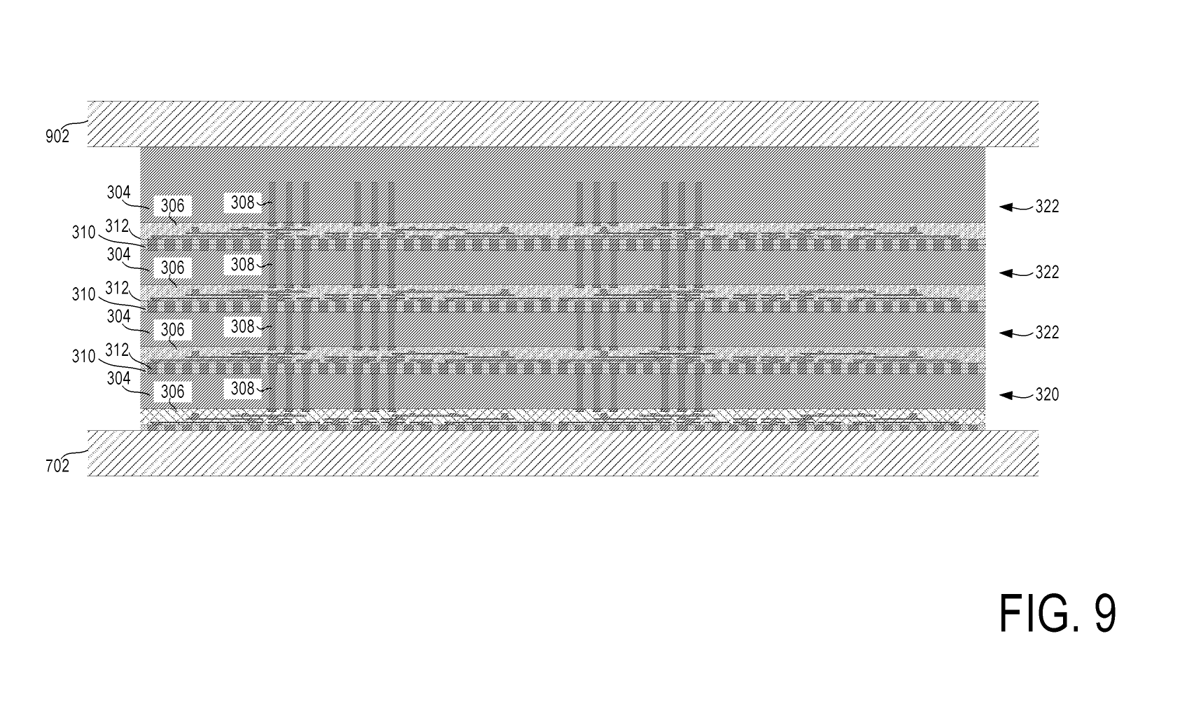

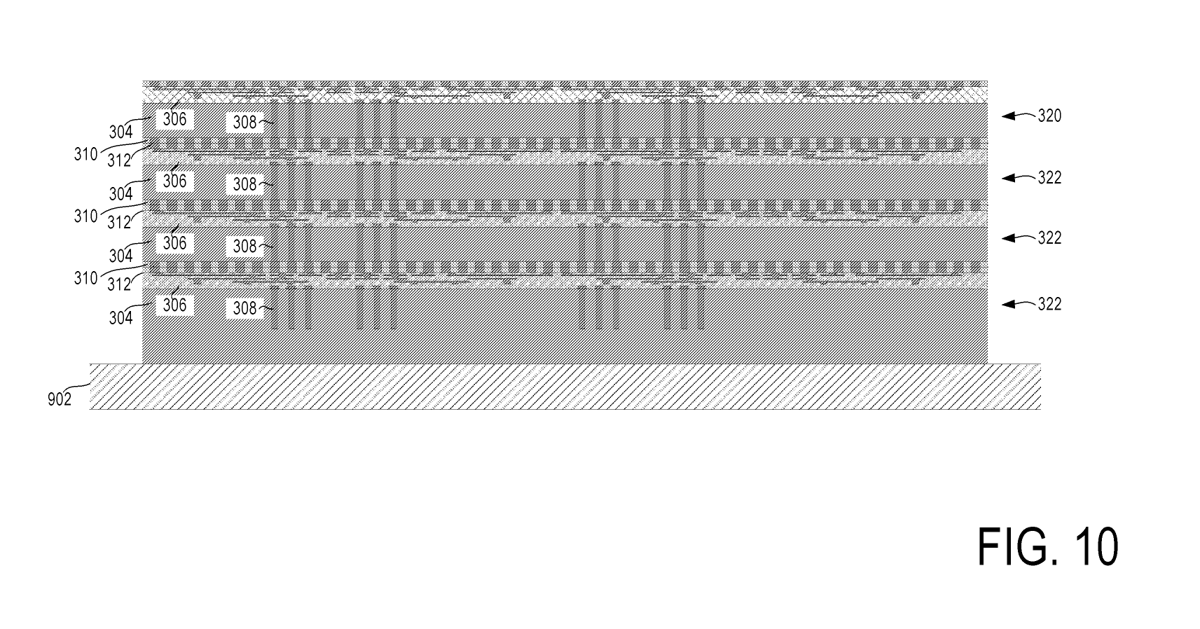

In block 606, a substrate 902 may be mounted on the top memory die 322, as shown in FIG. 9. In block 608, the assembly of dies 320, 322 is flipped over and the substrate 702 is removed, as shown in FIG. 10.

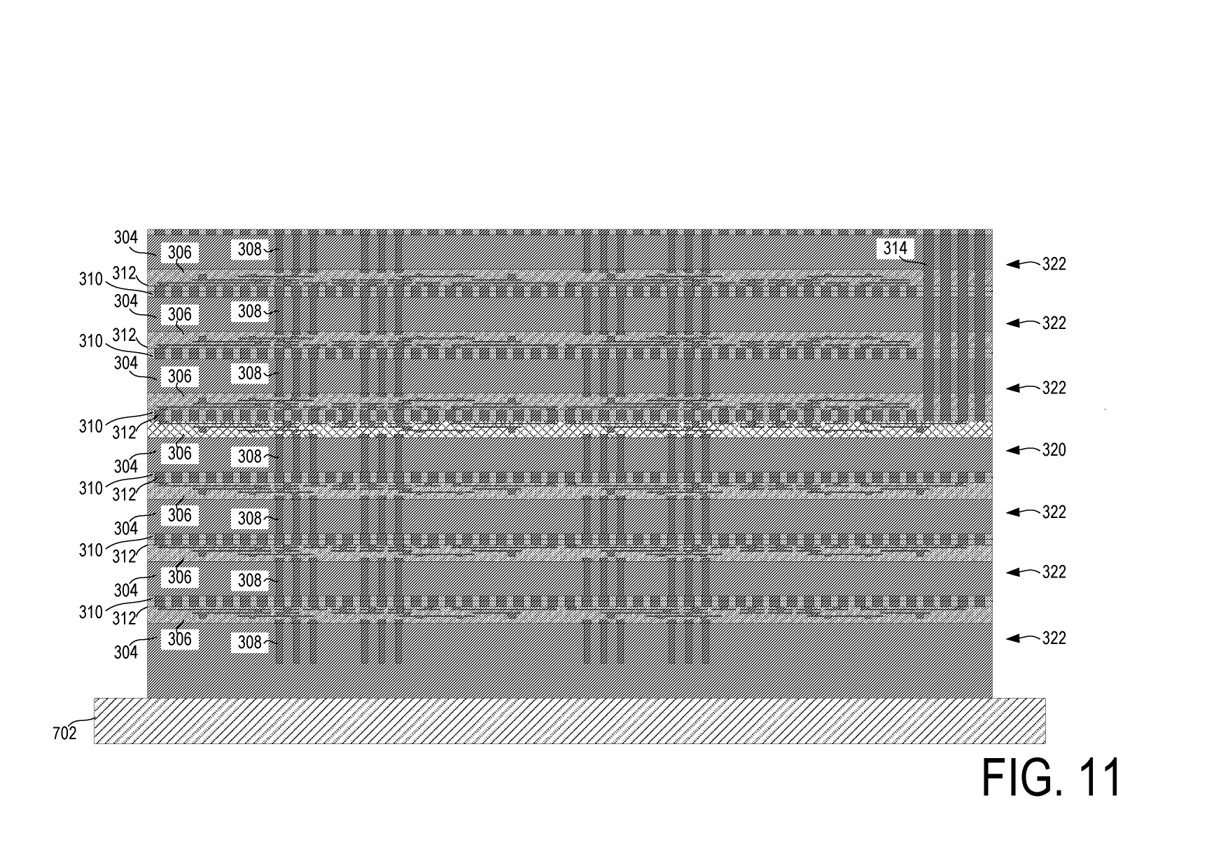

In block 610, additional HBM memory dies 322 are mounted on the interface die 320, as shown in FIG. 11. As discussed above, in an illustrative embodiment, backside processing may be performed on the memory dies 322 as they are added. Additionally or alternatively, no backside processing may be performed and/or more than one memory die 320 may be mounted at a time.

In an illustrative embodiment, vias 314 are added, extending from the top HBM memory die 322 to the interface memory die 320, as shown in FIG. 11. The vias 314 may be added as part of the backside processing of each layer. Additionally or alternatively, the vias 314 may be added through two or more (or all) HBM memory dies 320 after they are mounted.

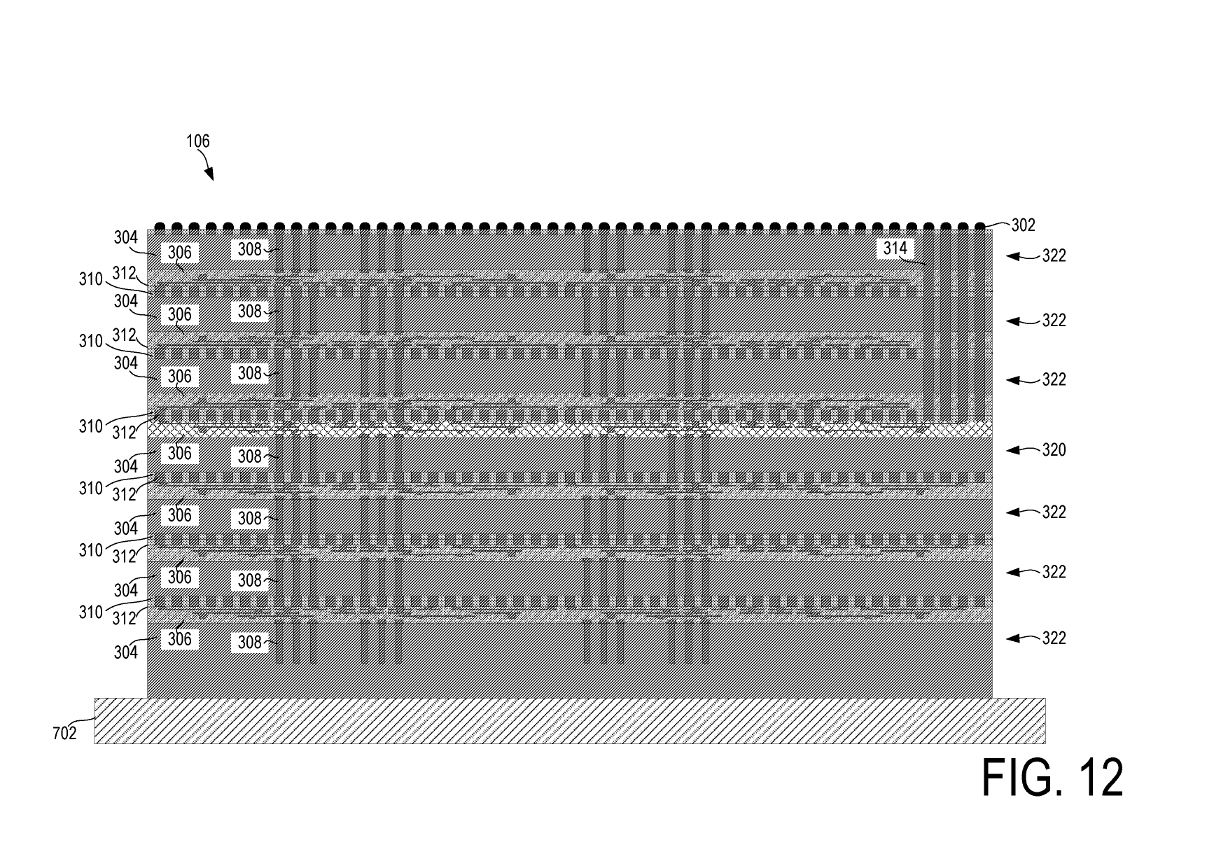

In block 612, microbumps 302 are formed on the top HBM die 322 in the HBM die stack 106, as shown in FIG. 12.

It should be appreciated that the method 600 described above is merely one possible embodiment, and other embodiments are envisioned as well. For example, in one embodiment, one or more HBM memory dies 320 may be mounted on the substrate 702 first, and the interface die 322 may be mounted on an HBM memory die 320. However, building up on the interface die 320 may provide certain advantages, such as being able to test connections and dies partway through the process. It should be appreciated that the method 600 and other embodiments for manufacturing the HBM die stack 106 may be performed at the die level or the wafer level.

In the illustrative embodiment, the interface die 320 with interface logic 316 directly connected to microbumps 302 is integrated into an HBM die stack 106. However, it should be appreciated that the concepts disclosed herein can be incorporated into any suitable component, such as any component with a stack of multiple dies with one die primarily or exclusively responsible for managing high-speed interconnects. Such a die may be placed at any suitable position in the stack, in accordance with the concepts and embodiments disclosed herein.

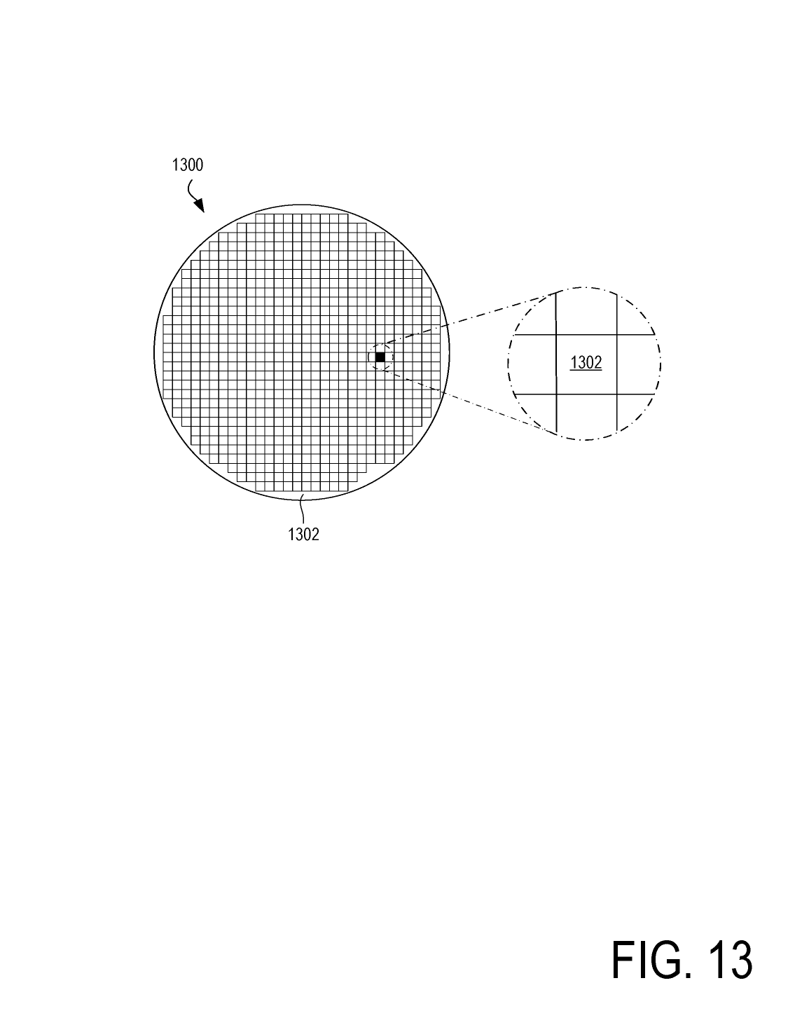

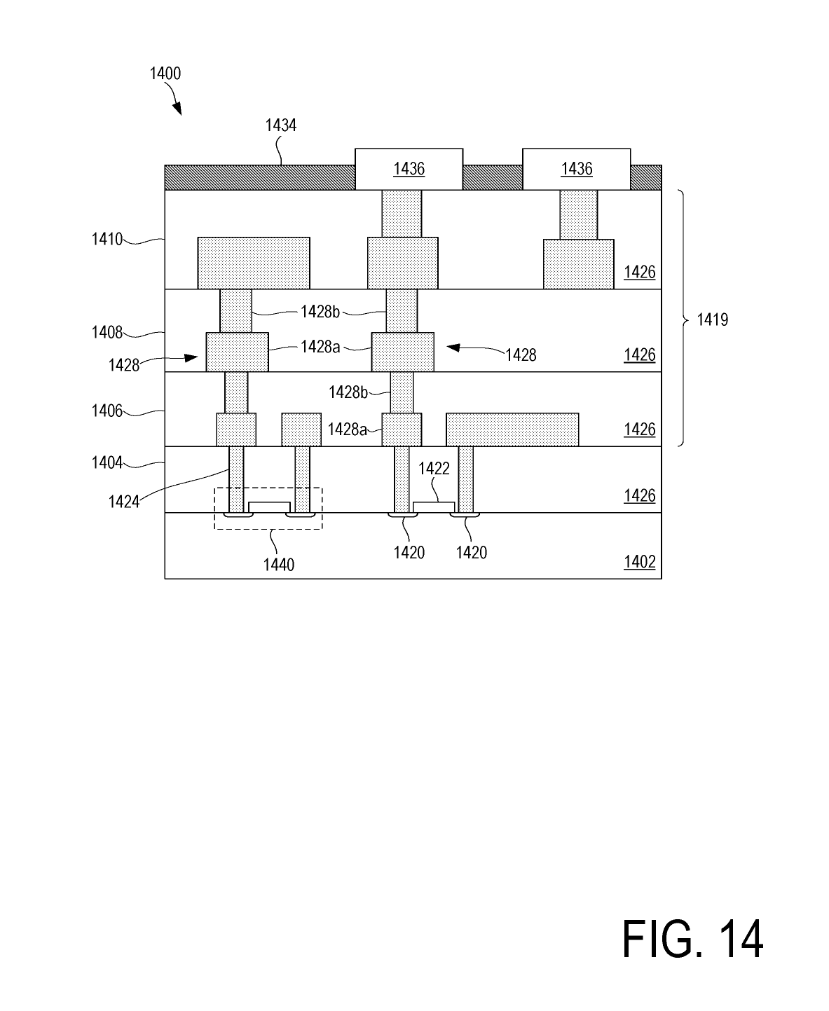

FIG. 13 is a top view of a wafer 1300 and dies 1302 that may be included in any of the integrated circuit components 100 disclosed herein (e.g., as any suitable ones of the dies 104, 320, 322). The wafer 1300 may be composed of semiconductor material and dies 1302 having integrated circuit structures formed on a surface of the wafer 1300. The individual dies 1302 may be a repeating unit of an integrated circuit product that includes any suitable integrated circuit. After the fabrication of the semiconductor product is complete, the wafer 1300 may undergo a singulation process in which the dies 1302 are separated from one another to provide discrete “chips” of the integrated circuit product. The dies 1302 may be any of the dies 104, 320, 322 disclosed herein. The dies 1302 may include one or more transistors (e.g., transistors 1440 of FIG. 14, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 1300 or the dies 1302 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Various ones of the integrated circuit components 100 disclosed herein may be manufactured using a die-to-wafer assembly technique in which some dies 104, 320, 322 are attached to a wafer 1300 that include others of the dies 104, 320, 322, and the wafer 1300 is subsequently singulated.

FIG. 14 is a cross-sectional view of an integrated circuit structure 1400 that may be included in any of the integrated circuit components 100 disclosed herein (e.g., in any of the dies 104, 320, 322). Multiple instances of the integrated circuit structure 1400 may be included in the dies 1302 (FIG. 13). The integrated circuit structure 1400 may be formed on a die substrate 1402. The die substrate 1402 may be a semiconductor substrate composed of semiconductor material including, for example, n-type or p-type materials (or a combination of both). The die substrate 1402 may include, for example, a crystalline substrate formed using a bulk silicon or a silicon-on-insulator (SOI) substructure. In some embodiments, the die substrate 1402 can comprise a layer of silicon on top of an SOI layer with bulk silicon below the SOI layer. In some embodiments, the die substrate 1402 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1402. Although a few examples of materials from which the die substrate 1402 may be formed are described here, any material that may serve as a foundation for an integrated circuit structure 1400 may be used. The die substrate 1402 may be part of a singulated die (e.g., dies 1302 of FIG. 13) or a wafer (e.g., wafer 1300 of FIG. 13).

The integrated circuit structure 1400 may include device layer 1404 disposed on the die substrate 1402. The device layer 1404 may include features of transistors 1440 (e.g., metal oxide semiconductor field-effect transistors (MOSFETs)) formed on the die substrate 1402. The transistors 1440 may include, for example, source and drain regions (S/D regions 1420), a gate 1422 to control current flow between the S/D regions 1420, and S/D contacts 1424 to route electrical signals to and from the S/D regions 1420. The transistors 1440 may include additional features not depicted for the sake of clarity, such as device isolation regions, gate contacts, and the like. The transistors 1440 are not limited to the type and configuration depicted in FIG. 14 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

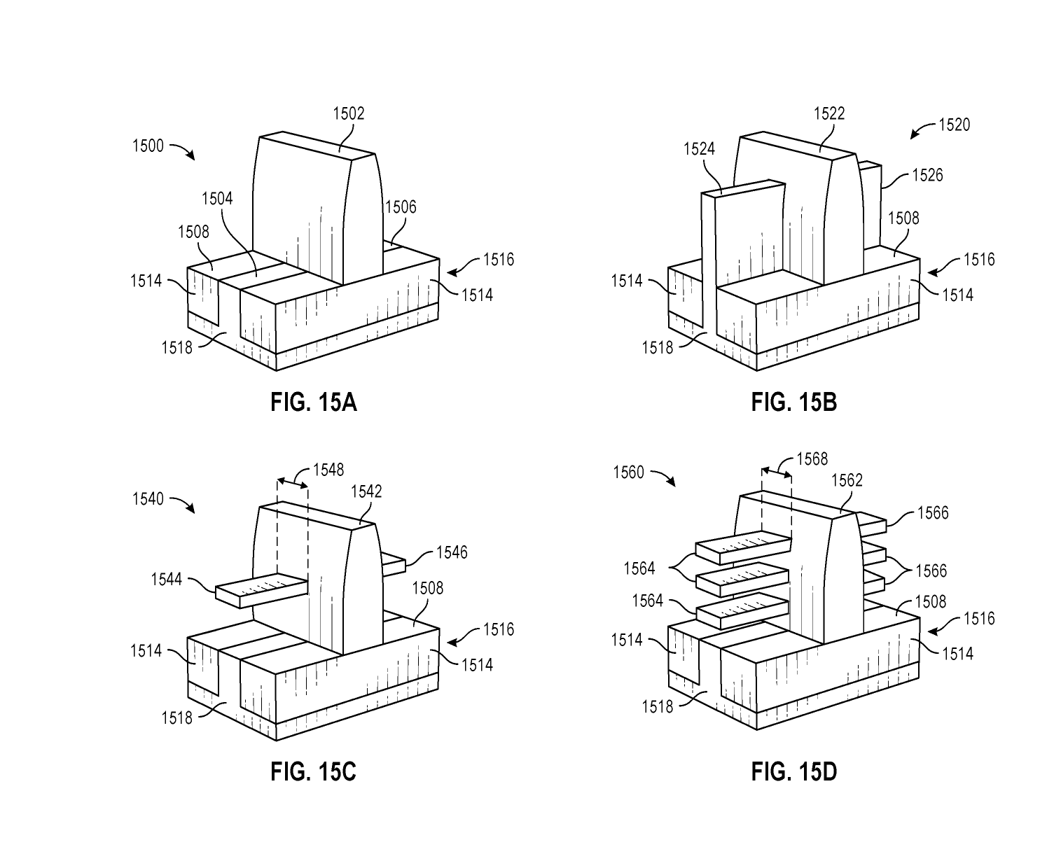

FIGS. 15A-15D are perspective views of example planar, FinFET, gate-all-around, and stacked gate-all-around transistors. The transistors illustrated in FIGS. 15A-15D are formed on a substrate 1516 having a substrate surface 1508 and a bulk region 1518. Isolation regions 1514 separate the source and drain regions of the transistors from other transistors.

FIG. 15A is a perspective view of an example transistor 1500 comprising a gate 1502 that controls current flow between a source region 1504 and a drain region 1506. The transistor 1500 is planar in that the source region 1504, the drain region 1506 and the substrate surface 1508 lie in the same plane.

FIG. 15B is a perspective view of an example transistor 1520 comprising a gate 1522 that controls current flow between a source region 1524 and a drain region 1526. The transistor 1520 is non-planar in that the source region 1524 and the drain region 1526 comprise “fins” that extend upwards from the substrate surface 1508. The transistor 1520 can be referred to as a FinFET. As the gate 1522 encompasses three sides of the fin that extends from the source region 1524 to the drain region 1526, the transistor 1520 can be considered a tri-gate transistor. FIG. 15B illustrates one S/D fin extending through the gate 1522, but multiple S/D fins can extend through the gate of a FinFET transistor.

FIG. 15C is a perspective view of a transistor 1540 comprising a gate 1542 that controls current flow between a source region 1544 and a drain region 1546. The transistor 1540 is non-planar in that the source region 1544 and the drain region 1546 lie in a different plane than the substrate surface 1508. As the gate 1542 encompasses all sides of the channel region of the transistor 1540 that extends from the source region 1544 to the drain region 1546, the transistor 1540 can be referred to as a gate-all-around (GAA) transistor.

FIG. 15D is a perspective view of a transistor 1560 comprising a gate 1562 that controls current flow between multiple elevated source regions 1564 and multiple elevated drain regions 1566. The transistor 1560 is a stacked GAA transistor as the gate controls the flow of current between multiple elevated S/D regions stacked on top of each other. The transistors 1540 and 1560 are considered gate-all-around transistors as the gates encompass all sides of the channel regions of the transistor that extends from the source regions to the drain regions. The transistors 1540 and 1560 can alternatively be referred to as nanowire, nanosheet, or nanoribbon transistors depending on the width (e.g., widths 1548 and 1568 of transistors 1540 and 1560, respectively) of the channel regions extending through the gate.

Returning to FIG. 14, transistors 1440 may include a gate 1422 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as in the FinFET illustrated in FIG. 15B, the gate electrode may have an upside-down U-shape that includes a top portion substantially parallel to the surface of the die substrate 1402 and two side portions that are substantially perpendicular to the top surface of the die substrate 1402. In other embodiments, such as the planar FET illustrated in FIG. 15A, at least one of the metal layers that form the gate electrode may be a planar layer that is substantially parallel to the top surface of the die substrate 1402 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 1420 may be formed within the die substrate 1402 adjacent to the gate 1422 of transistors 1440. The S/D regions 1420 may be formed using an implantation/diffusion process or an etching/deposition process, for example. In the former process, dopants such as boron, aluminum, antimony, phosphorous, or arsenic may be ion-implanted into the die substrate 1402 to form the S/D regions 1420. An annealing process that activates the dopants and causes them to diffuse further into the die substrate 1402 may follow the ion implantation process. In the latter process, the die substrate 1402 may first be etched to form recesses at the locations of the S/D regions 1420. An epitaxial deposition process may then be carried out to fill the recesses with material that is used to fabricate the S/D regions 1420. In some implementations, the S/D regions 1420 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1420 may be formed using one or more alternate semiconductor materials such as germanium or a group III-V material or alloy. In further embodiments, one or more layers of metal and/or metal alloys may be used to form the S/D regions 1420.

Electrical signals, such as power and/or information-carrying signals (e.g., input/output (I/O) signals, may be routed to and/or from devices (e.g., transistors 1440) of the device layer 1404 through one or more interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with interconnect structures 1428 of the interconnect layers 1406-1410. The one or more interconnect layers 1406-1410 may form a metallization stack 1419 (which can also be referred to as an “ILD stack” (inter-layer dielectric stack)) of the integrated circuit structure 1400.

The interconnect structures 1428 may be arranged within the interconnect layers 1406-1410 to route electrical signals according to a wide variety of designs; in particular, the arrangement is not limited to the particular configuration of interconnect structures 1428 depicted in FIG. 14. Although a particular number of interconnect layers 1406-1410 is depicted in FIG. 14, embodiments of the present disclosure include integrated circuit structures having more or fewer interconnect layers than depicted.

In some embodiments, the interconnect structures 1428 may include traces or lines 1428a and/or vias 1428b filled with an electrically conductive material such as a metal. The lines 1428a may be arranged to route electrical signals in a direction of a plane that is substantially parallel with a surface of the die substrate 1402 upon which the device layer 1404 is formed. For example, the lines 1428a may route electrical signals in a direction in and out of the page and/or in a direction across the page from the perspective of FIG. 14. The vias 1428b may be arranged to route electrical signals in a direction of a plane that is substantially perpendicular to the surface of the die substrate 1402 upon which the device layer 1404 is formed. In some embodiments, lines 1428a of different interconnect layers 1406-1410 are electrically coupled by vias 1428b.

The interconnect layers 1406-1410 may include a dielectric material 1426 within which the interconnect structures 1428 are disposed, as shown in FIG. 14. In some embodiments, dielectric material 1426 in different ones of the interconnect layers 1406-1410 may have different compositions; in other embodiments, the composition of the dielectric material 1426 between different interconnect layers 1406-1410 may be the same. The device layer 1404 may include a dielectric material 1426 within which the transistors 1440 are disposed and upon which a bottom layer of the metallization stack is located. The dielectric material 1426 that is part of the device layer 1404 may have a different composition than the dielectric material 1426 included in the interconnect layers 1406-1410; in other embodiments, the composition of the dielectric material 1426 in the device layer 1404 may be the same as a dielectric material 1426 included in any one of the interconnect layers 1406-1410.

A first interconnect layer 1406 (which can be referred to as a Metal 1 or “M1” layer) may be formed directly on the device layer 1404. In some embodiments, the first interconnect layer 1406 may include lines 1428a and/or vias 1428b, as shown. The lines 1428a of the first interconnect layer 1406 may be coupled with contacts (e.g., the S/D contacts 1424) of the device layer 1404. The vias 1428b of the first interconnect layer 1406 may be coupled with the lines 1428a of a second interconnect layer 1408.

The second interconnect layer 1408 (which can be referred to as a Metal 2 or “M2” layer) may be formed directly on the first interconnect layer 1406. In some embodiments, the second interconnect layer 1408 may include vias 1428b to couple the lines 1428a of the second interconnect layer 1408 with the lines 1428a of a third interconnect layer 1410. Although the lines 1428a and the vias 1428b are structurally delineated with a line within individual interconnect layers for the sake of clarity, the lines 1428a and the vias 1428b may be structurally and/or materially contiguous (e.g., simultaneously filled during a dual-damascene process) in some embodiments.

The third interconnect layer 1410 (which can be referred to as a Metal 3 or “M3” layer) (and additional interconnect layers, as desired) may be formed in succession on the second interconnect layer 1408 according to similar techniques and configurations described in connection with the second interconnect layer 1408 or the first interconnect layer 1406. In some embodiments, the interconnect layers that are “higher up” in the metallization stack 1419 in the integrated circuit structure 1400 (i.e., farther away from the device layer 1404) may be thicker than the interconnect layers that are lower in the metallization stack 1419, with lines 1428a and vias 1428b in the higher interconnect layers being thicker than those in the lower interconnect layers.

The integrated circuit structure 1400 may include a solder resist material 1434 (e.g., polyimide or similar material) and conductive contacts 1436 formed on the stack of interconnect layers 1406-1410. In FIG. 14, the conductive contacts 1436 are illustrated as taking the form of bond pads. The conductive contacts 1436 may be electrically coupled with interconnect structures 1428 of the top-most layer in the metallization stack 1419 and configured to route electrical signals between the transistors 1440 and components external to the integrated circuit structure 1400. For example, solder bonds may be formed on the conductive contacts 1436 to mechanically and/or electrically couple an integrated circuit component comprising the integrated circuit structure 1400 with another component (e.g., a printed circuit board). The integrated circuit structure 1400 may include additional or alternate structures to route electrical signals from the interconnect layers 1406-1410; for example, the conductive contacts 1436 may include other analogous features (e.g., posts) that can route the electrical signals between the transistors 1440 and external components. The conductive contacts 1436 may serve as the conductive contacts ### or ### , as appropriate.

In some embodiments in which the integrated circuit structure 1400 is part of a double-sided die (e.g., like the die ###), the integrated circuit structure 1400 may include a second metallization stack (not shown) located on the opposite side of the die substrate 1402 from the device layer 1404. This second metallization stack may include multiple interconnect layers as discussed above with reference to the interconnect layers 1406-1410. Through-silicon vias (TSVs) that extend through the die substrate 1402 can provide electrically conductive pathways from the transistors 1440 to the second metallization stack and the second metallizaton stack can electrically couple the TSVs to additional conductive contacts (not shown) located on the opposite side of the integrated circuit structure 1400 from the conductive contacts 1436. These additional conductive contacts may serve as the conductive pads 312, as appropriate.

In some embodiments, TSVs extending through the die substrate 1402 can be used for routing power and ground signals from conductive contacts located on the opposite side of the integrated circuit structure 1400 from the conductive contacts 1436 to the transistors 1440 and any other components integrated into the integrated circuit structure 1400, and the metallization stack 1419 can be used to route information-carrying signals from the conductive contacts 1436 to transistors 1440 and any other components integrated into the integrated circuit structure 1400. Put another way, the routing of power and ground signals to the transistors 1440 can be separated (via a back-side or bottom-side metallizaton stack and TSVs) from the routing of information-carrying signals to the transistors. The power and ground signals are provided by a backside or bottom-side metallization stack and TSVs, and information-carrying signals are provided by a topside metallization stack (e.g., metallization stack 1419).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

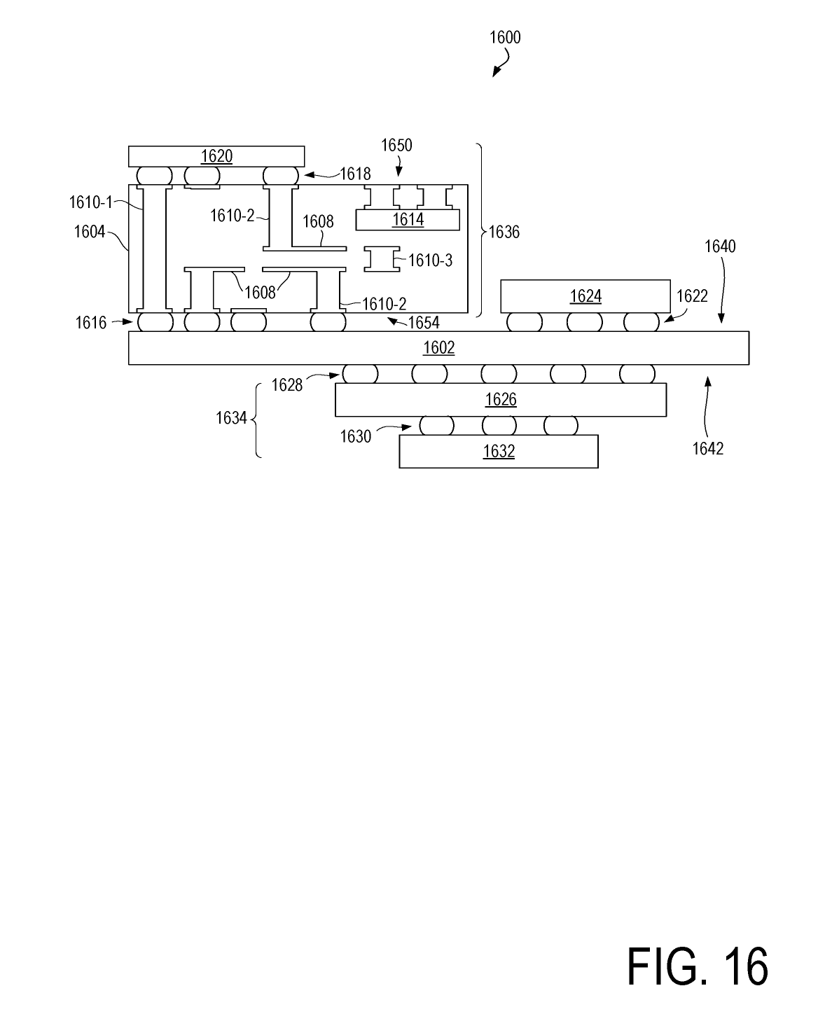

FIG. 16 is a cross-sectional view of an integrated circuit device assembly 1600 that may include any of the integrated circuit components 100 disclosed herein. In some embodiments, the integrated circuit device assembly 1600 may be an integrated circuit component 100. The integrated circuit device assembly 1600 includes a number of components disposed on a circuit board 1602 (which may be a motherboard, system board, mainboard, etc.). The integrated circuit device assembly 1600 includes components disposed on a first face 1640 of the circuit board 1602 and a second face 1642 of the circuit board 1602, the second face 1642 opposing the first face 1640. Generally, components may be disposed on either or both of the first face 1640 and the second face 1642 of the circuit board 1602. Any of the integrated circuit components discussed below with reference to the integrated circuit device assembly 1600 may take the form of any suitable ones of the embodiments of the integrated circuit components 100 disclosed herein.

In some embodiments, the circuit board 1602 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 1602. In other embodiments, the circuit board 1602 may be a non-PCB substrate. In some embodiments the circuit board 1602 may be, for example, the circuit board 102.

The integrated circuit device assembly 1600 illustrated in FIG. 16 includes a package-on-interposer structure 1636 coupled to the first face 1640 of the circuit board 1602 by coupling components 1616. The coupling components 1616 may electrically and mechanically couple the package-on-interposer structure 1636 to the circuit board 1602 and may include solder balls (as shown in FIG. 16), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. (Thus, a coupling component may comprise a conductive contact.) The coupling components 1616 may serve as the coupling components illustrated or described for any substrate assembly or substrate assembly components described herein (e.g., integrated circuit components), as appropriate.

The package-on-interposer structure 1636 may include an integrated circuit component 1620 coupled to an interposer 1604. The interposer 1604 may provide an intervening substrate used to bridge the circuit board 1602 and the integrated circuit component 1620. The integrated circuit component 1620 is coupled to the interposer 1604 by coupling components 1618. The coupling components 1618 may take any suitable form, such as the forms discussed above with reference to the coupling components 1616. Although FIG. 16 shows just one integrated circuit component attached to the interposer, multiple integrated circuit components may be coupled to the interposer 1604. Additional interposers may be coupled to the interposer 1604.

The integrated circuit component 1620 may be a packaged or unpacked integrated circuit product that includes one or more integrated circuit dies (e.g., the die 1302 of FIG. 13, a die comprising the integrated circuit structure 1400 of FIG. 14) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 1620, a single monolithic integrated circuit die comprises solder bumps attached to contacts on the die. The solder bumps allow the die to be directly attached to the interposer 1604. The integrated circuit component 1620 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1620 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1620 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1620 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1604 may spread connections to a wider or narrower pitch or reroute a connection to a different connection. For example, the interposer 1604 may couple coupling components 1618 having a first pitch to coupling components 1616 having a wider pitch than the first pitch. In the embodiment illustrated in FIG. 16, the integrated circuit component 1620 and the circuit board 1602 are attached to opposing sides of the interposer 1604. In other embodiments, the integrated circuit component 1620 and the circuit board 1602 may be attached to a same side of the interposer 1604. In some embodiments, three or more components may be interconnected by way of the interposer 1604.

In some embodiments, the interposer 1604 may be formed as a PCB, including multiple metal layers separated from one another by layers of dielectric material and interconnected by electrically conductive vias. In some embodiments, the interposer 1604 may be formed of an epoxy resin, a fiberglass-reinforced epoxy resin, an epoxy resin with inorganic fillers, a ceramic material, or a polymer material such as polyimide. In some embodiments, the interposer 1604 may be formed of alternate rigid or flexible materials that may include the same materials described above for use in a semiconductor substrate, such as silicon, germanium, and other group III-V and group IV materials. The interposer 1604 may include metal interconnects 1608 and vias, including but not limited to through hole vias 1610-1 (that extend from a first face 1650 of the interposer 1604 to a second face 1654 of the interposer 1604), blind vias 1610-2 (that extend from the first face 1650 or the second face 1654 of the interposer 1604 to an internal metal layer), and buried vias 1610-3 (that connect internal metal layers).

In some embodiments, the interposer 1604 can comprise a silicon interposer. Through silicon vias (TSV) extending through the silicon interposer can connect connections on a first face of a silicon interposer to an opposing second face of the silicon interposer. In some embodiments, an interposer 1604 comprising a silicon interposer can further comprise one or more routing layers to route connections on a first face of the interposer 1604 to an opposing second face of the interposer 1604.

In some embodiments the interposer 1604, as well as the circuit board 1602, can comprise an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂O), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm x 10 mm to about 250 mm x 250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 1604 or circuit board 1602 to the glass layer. The glass layer can comprise through-glass vias (TGVs) that extend through the glass layer to provide electrically conductive paths through the glass core, glass substrate, or glass layer.

The interposer 1604 may further include embedded devices 1614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1604. The package-on-interposer structure 1636 may take the form of any of the package-on-interposer structures known in the art.

The integrated circuit device assembly 1600 may include an integrated circuit component 1624 coupled to the first face 1640 of the circuit board 1602 by coupling components 1622. The coupling components 1622 may take the form of any of the embodiments discussed above with reference to the coupling components 1616, and the integrated circuit component 1624 may take the form of any of the embodiments discussed above with reference to the integrated circuit component 1620.

The integrated circuit device assembly 1600 illustrated in FIG. 16 further includes a package-on-package structure 1634 coupled to the second face 1642 of the circuit board 1602 by coupling components 1628. The package-on-package structure 1634 may include an integrated circuit component 1626 and an integrated circuit component 1632 coupled together by coupling components 1630 such that the integrated circuit component 1626 is disposed between the circuit board 1602 and the integrated circuit component 1632. The coupling components 1628 and 1630 may take the form of any of the embodiments of the coupling components 1616 discussed above, and the integrated circuit components 1626 and 1632 may take the form of any of the embodiments of the integrated circuit component 1620 discussed above. The package-on-package structure 1634 may be configured in accordance with any of the package-on-package structures known in the art.

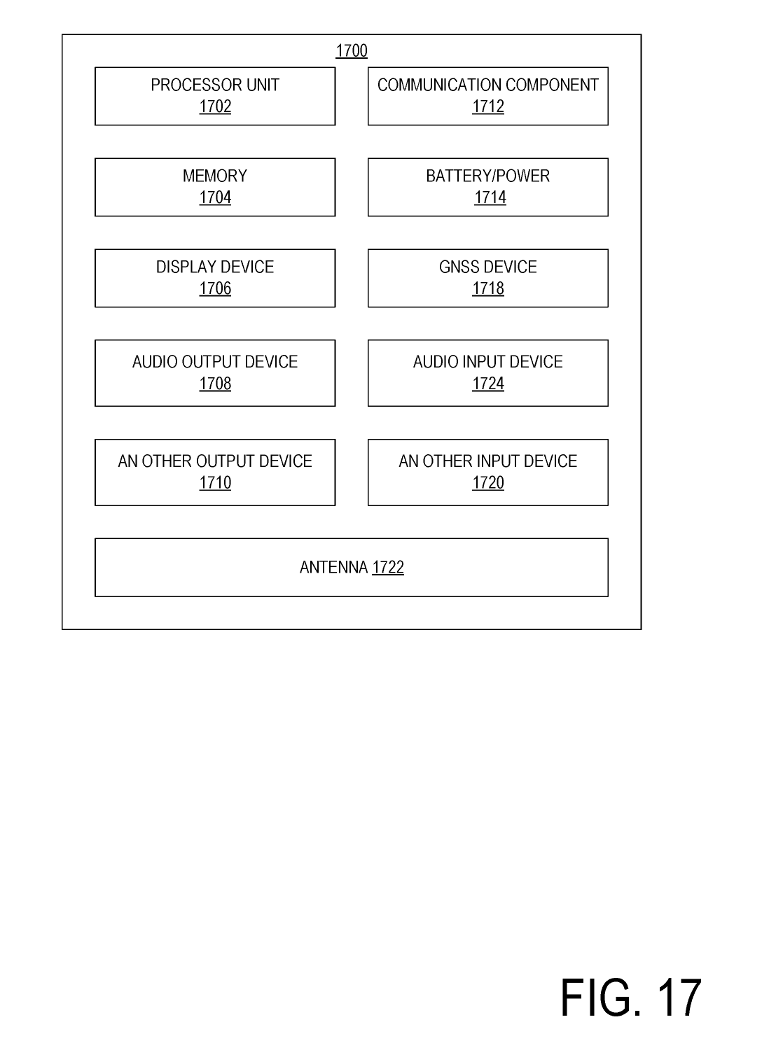

FIG. 17 is a block diagram of an example electrical device 1700 that may include any of the microelectronic assemblies disclosed herein. For example, any suitable ones of the components of the electrical device 1700 may include one or more of the integrated circuit device assembly 1600, integrated circuit component 1620, or integrated circuit structure 1400, integrated circuit dies 1302 disclosed herein, and may be arranged in any of the integrated circuit components 100 disclosed herein. A number of components are illustrated in FIG. 17 as included in the electrical device 1700, but any one or more of these components may be omitted or duplicated, as suitable for the application. In some embodiments, some or all of the components included in the electrical device 1700 may be attached to one or more motherboards mainboards, or system boards. In some embodiments, one or more of these components are fabricated onto a single system-on-a-chip (SoC) die.

Additionally, in various embodiments, the electrical device 1700 may not include one or more of the components illustrated in FIG. 17, but the electrical device 1700 may include interface circuitry for coupling to the one or more components. For example, the electrical device 1700 may not include a display device 1706, but may include display device interface circuitry (e.g., a connector and driver circuitry) to which a display device 1706 may be coupled. In another set of examples, the electrical device 1700 may not include an audio input device 1724 or an audio output device 1708, but may include audio input or output device interface circuitry (e.g., connectors and supporting circuitry) to which an audio input device 1724 or audio output device 1708 may be coupled.

The electrical device 1700 may include one or more processor units 1702. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 1702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1700 may include a memory 1704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1704 may include memory that is located on the same integrated circuit die as the one or more processor units 1702. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 1700, a first one of the one or more processor units 1702 can be heterogeneous or asymmetric to a second one of the one or more processor units 1702 in the electrical device 1700. There can be a variety of differences between the one or more processor units 1702 in a system in terms of a spectrum of metrics of merit including architectural, microarchitectural, thermal, power consumption characteristics, and the like. These differences can effectively manifest themselves as asymmetry and heterogeneity among the one or more processor units 1702 in the electrical device 1700.

In some embodiments, the electrical device 1700 may include a communication component 1712. For example, the communication component 1712 can manage wireless communications for the transfer of data to and from the electrical device 1700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1712 may operate in accordance with other wireless protocols in other embodiments. The electrical device 1700 may include an antenna 1722 to facilitate wireless communications and/or to receive other wireless communications (such as AM or FM radio transmissions).

In some embodiments, the communication component 1712 may manage wired communications, such as electrical, optical, or any other suitable communication protocols (e.g., IEEE 802.3 Ethernet standards). In some embodiments, the electrical device 1700 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 1700 may include battery/power circuitry 1714. The battery/power circuitry 1714 may include one or more energy storage devices (e.g., batteries or capacitors) and/or circuitry for coupling components of the electrical device 1700 to an energy source separate from the electrical device 1700 (e.g., AC line power).

The electrical device 1700 may include a display device 1706 (or corresponding interface circuitry, as discussed above). The display device 1706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1700 may include an audio output device 1708 (or corresponding interface circuitry, as discussed above). The audio output device 1708 may include any embedded or wired or wirelessly connected external device that generates an audible indicator, such as speakers, headsets, or earbuds.

The electrical device 1700 may include an audio input device 1724 (or corresponding interface circuitry, as discussed above). The audio input device 1724 may include any embedded or wired or wirelessly connected device that generates a signal representative of a sound, such as microphones, microphone arrays, or digital instruments (e.g., instruments having a musical instrument digital interface (MIDI) output). The electrical device 1700 may include a Global Navigation Satellite System device (GNSS) (or corresponding interface circuitry, as discussed above), such as a Global Positioning System (GPS) device. The GNSS device 1718 may be in communication with a satellite-based system and may determine a geolocation of the electrical device 1700 based on information received from one or more GNSS satellites, as known in the art.

The electrical device 1700 may include another output device 1710 (or corresponding interface circuitry, as discussed above). Examples of the other output device 1710 may include an audio codec, a video codec, a printer, a wired or wireless transmitter for providing information to other devices, or an additional storage device.

The electrical device 1700 may include another input device 1720 (or corresponding interface circuitry, as discussed above). Examples of the other input device 1720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1700 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1700 may be any other electronic device that processes data. In some embodiments, the electrical device 1700 may comprise multiple discrete physical components. Given the range of devices that the electrical device 1700 can be manifested as in various embodiments, in some embodiments, the electrical device 1700 can be referred to as a computing device or a computing system.

### EXAMPLES

Illustrative examples of the technologies disclosed herein are provided below. An embodiment of the technologies may include any one or more, and any combination of, the examples described below.

Example 1 includes an apparatus comprising a semiconductor die stack comprising a first plurality of semiconductor dies; an interface die comprising a top surface and a bottom surface; and a second plurality of semiconductor dies, wherein the first plurality of semiconductor dies is adjacent to the top surface of the interface die, and wherein the second plurality of semiconductor dies is adjacent to the bottom surface of the interface die.

Example 2 includes the subject matter of Example 1, and wherein the second plurality of semiconductor dies comprises a top surface and a bottom surface, wherein the top surface of the second plurality of semiconductor dies is adjacent to the interface die, further comprising a plurality of conductive bumps adjacent the bottom surface of the second plurality of semiconductor dies; and a plurality of through-silicon vias extending from the interface die to the plurality of conductive bumps.

Example 3 includes the subject matter of any of Examples 1 and 2, and wherein the plurality of through-silicon vias is a plurality of supervias.

Example 4 includes the subject matter of any of Examples 1-3, and wherein the interface die is disposed in a middle layer of the semiconductor die stack, with an equal number of semiconductor dies above and below the interface die.

Example 5 includes the subject matter of any of Examples 1-4, and wherein individual semiconductor dies of the first and second plurality of semiconductor dies comprises one or more conductive traces coupled to the interface die.

Example 6 includes the subject matter of any of Examples 1-5, and wherein a signal path length to the interface die is defined between individual conductive traces of the one or more conductive traces of individual semiconductor dies of the first and second plurality of semiconductor dies, wherein, for individual semiconductor dies of the first plurality of semiconductor dies, the signal path length to the interface die of the one or more conductive traces is balanced with those of a semiconductor die of the second plurality of semiconductor dies.

Example 7 includes the subject matter of any of Examples 1-6, and wherein there are more semiconductor dies in the semiconductor die stack below the interface die than above the interface die.

Example 8 includes the subject matter of any of Examples 1-7, and wherein the first plurality of semiconductor dies comprises at least four memory dies, wherein the second plurality of semiconductor dies comprises at least four memory dies.

Example 9 includes the subject matter of any of Examples 1-8, and wherein the first plurality of semiconductor dies comprises at least sixteen memory dies, wherein the second plurality of semiconductor dies comprises at least sixteen memory dies.

Example 10 includes the subject matter of any of Examples 1-9, and wherein the semiconductor die stack is a high-bandwidth memory (HBM) die stack.

Example 11 includes the subject matter of any of Examples 1-10, and further including an integrated circuit component, the integrated circuit component comprising a circuit board, a processor die, a bridge die, and the semiconductor die stack, wherein the bridge die electrically couples the processor die and the semiconductor die stack.

Example 12 includes an apparatus comprising a high-bandwidth memory die stack comprising a stack of one or more memory dies, the stack of one or more memory dies comprising a top surface and a bottom surface; an interface die comprising a top surface and a bottom surface, wherein the stack of one or more memory dies is adjacent to the bottom surface of the interface die; and a plurality of conductive bumps adjacent the bottom surface of the stack of one or more memory dies.

Example 13 includes the subject matter of Example 12, and wherein the top surface of the interface die is adjacent an integrated heat spreader or heat sink.

Example 14 includes the subject matter of any of Examples 12 and 13, and wherein the stack of one or more memory dies comprises a top surface and a bottom surface, wherein the top surface of the stack of one or more memory dies is adjacent to the interface die, further comprising a plurality of conductive bumps adjacent the bottom surface of the stack of one or more memory dies; and a plurality of through-silicon vias extending from the interface die to the plurality of conductive bumps.

Example 15 includes the subject matter of any of Examples 12-14, and wherein the plurality of through-silicon vias is a plurality of supervias.

Example 16 includes the subject matter of any of Examples 12-15, and wherein there are more semiconductor dies in the high-bandwidth memory die stack below the interface die than above the interface die.

Example 17 includes the subject matter of any of Examples 12-16, and wherein the stack of one or more memory dies comprises at least four memory dies.

Example 18 includes the subject matter of any of Examples 12-17, and wherein the stack of one or more memory dies comprises at least sixteen memory dies.

Example 19 includes the subject matter of any of Examples 12-18, and further including an integrated circuit component, the integrated circuit component comprising a circuit board, a processor die, a bridge die, and the high-bandwidth memory die stack, wherein the bridge die electrically couples the processor die and the high-bandwidth memory die stack.

Example 20 includes an apparatus comprising a high-bandwidth memory die stack comprising a plurality of memory dies, wherein individual memory dies of the plurality of memory dies comprise a plurality of memory cells; an interface die, wherein the interface die is disposed above one or more of the plurality of memory dies and disposed below one or more of the plurality of memory dies, wherein the interface die comprises a memory controller, wherein the memory controller is electronically coupled to the plurality of memory cells on individual memory dies of the plurality of memory dies; and a plurality of vias extending from the interface die, through one or more memory dies of the plurality of memory dies, to a bottom surface of the plurality of memory dies, wherein the plurality of vias are electronically coupled to the memory controller.

Example 21 includes the subject matter of Example 20, and wherein the plurality of vias is a plurality of supervias.

Example 22 includes the subject matter of any of Examples 20 and 21, and wherein the interface die is disposed in a middle of the plurality of memory dies, with an equal number of memory dies above and below the interface die.

Example 23 includes the subject matter of any of Examples 20-22, and wherein individual memory dies of the plurality of memory dies comprises one or more conductive traces coupled to the interface die.

Example 24 includes the subject matter of any of Examples 20-23, and wherein a signal path length to the interface die is defined between individual conductive traces of the one or more conductive traces of individual memory dies of the plurality of memory dies, wherein, for individual memory dies of a first plurality of memory dies of the plurality of memory dies above the interface die, the signal path length to the interface die of the one or more conductive traces is balanced with those of a semiconductor die of a second plurality of memory dies of the plurality of memory dies below the interface die.

Example 25 includes the subject matter of any of Examples 20-24, and wherein there are more memory dies in the plurality of memory dies below the interface die than above the interface die.

Example 26 includes the subject matter of any of Examples 20-25, and further including an integrated circuit component, the integrated circuit component comprising a circuit board, a processor die, a bridge die, and the high-bandwidth memory die stack, wherein the bridge die electrically couples the processor die and the high-bandwidth memory die stack.

Example 27 includes a method for forming a high-bandwidth memory die stack comprising bonding a first plurality of high-bandwidth memory dies on a first side of an interface die; and bonding a second plurality of high-bandwidth memory dies on a second side of an interface side, the second side opposite the first side.

Example 28 includes the subject matter of Example 27, and wherein bonding the first plurality of high-bandwidth memory dies comprises mounting the interface die on a first carrier substrate; and bonding the first plurality of high-bandwidth memory dies while the interface die is attached to the first carrier substrate.

Example 29 includes the subject matter of any of Examples 27 and 28, and wherein bonding the second plurality of high-bandwidth memory dies comprises mounting a second carrier substrate on the first plurality of high-bandwidth memory dies; removing the first carrier substrate; and bonding the second plurality of high-bandwidth memory dies while the first plurality of high-bandwidth memory dies is attached to the second carrier substrate.

Example 30 includes the subject matter of any of Examples 27-29, and further including forming a plurality of microbumps on the second plurality of high-bandwidth memory dies.

1. An apparatus comprising:
a semiconductor die stack comprising:
a first plurality of semiconductor dies;
an interface die comprising a top surface and a bottom surface; and
a second plurality of semiconductor dies,
wherein the first plurality of semiconductor dies is adjacent to the top surface of the interface die, and wherein the second plurality of semiconductor dies is adjacent to the bottom surface of the interface die.

2. The apparatus of claim 1, wherein the second plurality of semiconductor dies comprises a top surface and a bottom surface, wherein the top surface of the second plurality of semiconductor dies is adjacent to the interface die, further comprising:
a plurality of conductive bumps adjacent the bottom surface of the second plurality of semiconductor dies; and
a plurality of through-silicon vias extending from the interface die to the plurality of conductive bumps.

3. The apparatus of claim 2, wherein the plurality of through-silicon vias is a plurality of supervias.

4. The apparatus of claim 1, wherein the interface die is disposed in a middle layer of the semiconductor die stack, with an equal number of semiconductor dies above and below the interface die.

5. The apparatus of claim 1, wherein individual semiconductor dies of the first and second plurality of semiconductor dies comprises one or more conductive traces coupled to the interface die.

6. The apparatus of claim 5, wherein a signal path length to the interface die is defined between individual conductive traces of the one or more conductive traces of individual semiconductor dies of the first and second plurality of semiconductor dies,
wherein, for individual semiconductor dies of the first plurality of semiconductor dies, the signal path length to the interface die of the one or more conductive traces is balanced with those of a semiconductor die of the second plurality of semiconductor dies.

7. The apparatus of claim 1, wherein there are more semiconductor dies in the semiconductor die stack below the interface die than above the interface die.

8. The apparatus of claim 1, wherein the first plurality of semiconductor dies comprises at least four memory dies, wherein the second plurality of semiconductor dies comprises at least four memory dies.

9. The apparatus of claim 1, wherein the first plurality of semiconductor dies comprises at least sixteen memory dies, wherein the second plurality of semiconductor dies comprises at least sixteen memory dies.

10. The apparatus of claim 1, wherein the semiconductor die stack is a high-bandwidth memory (HBM) die stack.

11. The apparatus of claim 1, further comprising an integrated circuit component, the integrated circuit component comprising a circuit board, a processor die, a bridge die, and the semiconductor die stack, wherein the bridge die electrically couples the processor die and the semiconductor die stack.

12. An apparatus comprising:
a high-bandwidth memory die stack comprising:
a stack of one or more memory dies, the stack of one or more memory dies comprising a top surface and a bottom surface;
an interface die comprising a top surface and a bottom surface, wherein the stack of one or more memory dies is adjacent to the bottom surface of the interface die; and
a plurality of conductive bumps adjacent the bottom surface of the stack of one or more memory dies.

13. The apparatus of claim 12, wherein the top surface of the interface die is adjacent an integrated heat spreader or heat sink.

14. The apparatus of claim 12, wherein the stack of one or more memory dies comprises a top surface and a bottom surface, wherein the top surface of the stack of one or more memory dies is adjacent to the interface die, further comprising:
a plurality of conductive bumps adjacent the bottom surface of the stack of one or more memory dies; and
a plurality of through-silicon vias extending from the interface die to the plurality of conductive bumps.

15. The apparatus of claim 14, wherein the plurality of through-silicon vias is a plurality of supervias.

16. The apparatus of claim 12, wherein there are more semiconductor dies in the high-bandwidth memory die stack below the interface die than above the interface die.

17. The apparatus of claim 12, wherein the stack of one or more memory dies comprises at least four memory dies.

18. The apparatus of claim 12, further comprising an integrated circuit component, the integrated circuit component comprising a circuit board, a processor die, a bridge die, and the high-bandwidth memory die stack, wherein the bridge die electrically couples the processor die and the high-bandwidth memory die stack.

19. An apparatus comprising:
a high-bandwidth memory die stack comprising:
a plurality of memory dies, wherein individual memory dies of the plurality of memory dies comprise a plurality of memory cells;
an interface die, wherein the interface die is disposed above one or more of the plurality of memory dies and disposed below one or more of the plurality of memory dies, wherein the interface die comprises a memory controller, wherein the memory controller is electronically coupled to the plurality of memory cells on individual memory dies of the plurality of memory dies; and
a plurality of vias extending from the interface die, through one or more memory dies of the plurality of memory dies, to a bottom surface of the plurality of memory dies, wherein the plurality of vias are electronically coupled to the memory controller.

20. The apparatus of claim 19, wherein individual memory dies of the plurality of memory dies comprises one or more conductive traces coupled to the interface die,
wherein a signal path length to the interface die is defined between individual conductive traces of the one or more conductive traces of individual memory dies of the plurality of memory dies,
wherein, for individual memory dies of a first plurality of memory dies of the plurality of memory dies above the interface die, the signal path length to the interface die of the one or more conductive traces is balanced with those of a semiconductor die of a second plurality of memory dies of the plurality of memory dies below the interface die.
